(19) United States
(12) Patent Application Publication
(10) Pub. No.: US 2008/0149032 A1
(43) Pub. Date: Jun. 26, 2008

(54) LIFT PIN, APPARATUS FOR PROCESSING A SUBSTRATE AND METHOD OF PROCESSING A SUBSTRATE

(76) Inventor: Soon-Bin Jung, Yongin-si (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/764,482

(22) Filed: Jun. 18, 2007

(30) Foreign Application Priority Data
Dec. 22, 2006 (KR) 10-2006-0132393

(51) Int. Cl. C23C 16/00

(52) U.S. Cl. 118/728; 118/715; 427/255.5

(57) ABSTRACT

Disclosed are a lift pin, an apparatus for processing a substrate and a method of processing a substrate. The lift pin includes a rod portion and a head portion. The rod portion moves in a passage formed through a chuck having a substrate processed using a reaction gas. The head portion is provided on the rod portion to make contact with the substrate. The head portion may close the passage to prevent the reaction gas from flowing into the passage.

### CROSS-REFERENCE TO RELATED APPLICATION

This application claims priority under 35 USC § 119 to Korean Patent Application No. 2006-132393 filed on Dec. 22, 2006, the contents of which are herein incorporated by references in their entirety.

### BACKGROUND OF THE INVENTION

1. Field of the Invention

Example embodiments of the present invention relate to a lift pin, an apparatus for processing a substrate and a method of processing a substrate. More particularly, example embodiments of the present invention relate to a lift pin for moving a substrate in a desired direction to place the substrate on a chuck, an apparatus including the lift pin for processing a substrate, and a method of processing the substrate using the apparatus.

2. Description of the Related Art

Semiconductor devices are usually manufactured through a series of processes such as a deposition process for forming a layer, a photo process, a lithography process, a diffusion process, etc. As for the deposition process for forming a layer on a substrate, there have been developed various processes, for example, a sputtering process, an electroplating process, an evaporation process, a chemical vapor deposition (CVD) process, a molecular beam epitaxy process, an atomic layer deposition (ALD) process, etc.

Since the CVD process provides a layer having excellent characteristics, the CVD process has been widely employed for forming a desired layer on a substrate. The CVD process generally includes a low pressure chemical vapor deposition (LPCVD) process, an atmospheric pressure chemical vapor deposition (APCVD) process, a low temperature chemical vapor deposition (LTCVD) process, a plasma-enhanced chemical vapor deposition (PECVD) process, etc.

A conventional chemical vapor deposition (CVD) apparatus generally includes a chamber, an electrostatic chuck (ESC), a shower head and a lift pin. A substrate where a layer is formed is loaded in the chamber. The substrate is mounted on the ESC installed in the chamber. The shower head is positioned over the ESC so as to provide a reaction gas onto the substrate. The lift pin is inserted in a passage vertically formed through the ESC to move the substrate along an upward direction or a downward direction. For example, the conventional CVD apparatus having a lift pin is disclosed in Korean Laid-Open Patent Publication No. 2005-42965.

The lift pin in the conventional CVD apparatus moves upwardly and downwardly in the passage formed through the ESC so that the lift pin has a diameter smaller than that of the passage. Particularly, since the lift pin of the conventional CVD apparatus has a constant diameter, a gap is generated between the lift pin and an inner face of the passage. Thus, the reaction gas for forming the layer flows into the passage through the gap while forming the layer on the substrate. Additionally, reaction by-products flow into the passage through the gap between the lift pin and the passage. As a result, an undesired layer is formed on the inner face of the passage. The undesired layer formed on the passage may serve as particles that cause various failures of a semiconductor device. Further, the undesired layer is continuously formed on the inner face of the passage such that the diameter of the passage is also continuously reduced, thereby preventing the lift pin from moving upwardly and downwardly.

### SUMMARY OF THE INVENTION

Example embodiments of the present invention provide a lift pin capable of preventing an inflow of a reaction gas toward a passage of a chuck.

Example embodiments of the present invention provide an apparatus for processing a substrate, which includes a lift pin capable of preventing an inflow of a reaction gas toward a passage of a chuck.

Example embodiments of the present invention provide a method of processing a substrate using the above apparatus including a lift pin capable of preventing an inflow of a reaction gas toward a passage of a chuck.

According to one aspect of the present invention, there is provided a lift pin including a rod portion and a head portion. The rod portion may move in a passage formed through a chuck having an object processed using a reaction gas. The head portion may be provided on the rod portion to make contact with the object. The head portion may close the passage to prevent the reaction gas from flowing into the passage.

In example embodiments of the present invention, the head portion may have a lower portion making contact with an upper face of the passage of the chuck.

In example embodiments of the present invention, a receiving groove may be provided on the chuck to receive the head portion. Here, the head portion may have a side separated from an inner face of the receiving groove communicating with the passage.

In example embodiments of the present invention, a receiving groove may be provided on the chuck to receive the head portion. The head portion may have a side making contact with an inner face of the receiving groove communicating with the passage.

In example embodiments of the present invention, an upper portion of the head portion may be substantially smaller than a lower portion of the head portion. For example, the head portion may have an arch-shaped cross-section, a semicircular cross-section, a triangular cross-section, a rectangular cross-section, a trapezoid cross-section or a funneled cross-section.

According to another aspect of the present invention, there is provided an apparatus for processing a substrate. The apparatus includes a chamber, a chuck, a shower head and a lift pin. The chamber may receive a substrate therein. The chuck may be disposed in the chamber to support the substrate. The chuck may have a passage formed along a direction substantially perpendicular to the substrate. The shower head may be disposed over the chuck to provide a reaction gas onto the substrate. The lift pin may be disposed in the passage to move the substrate along an upward direction and a downward direction. The lift pin may include a rod portion moving in the passage and a head portion formed on the rod portion to prevent the reaction gas from flowing into the passage.

In example embodiments of the present invention, an upper portion of the head portion of the lift pin may be substantially smaller than a lower portion of the head portion. The head portion may have an arch-shaped cross-section, a semicircular cross-section, a polygonal cross-section or a funneled cross-section.

In example embodiments of the present invention, the chuck may have a receiving groove where the head portion is received. The receiving groove may have a depth substantially the same as or larger than a thickness of the head portion. The receiving groove may have an inner face making contact with a side face of the head portion. Alternatively, the receiving groove may have an inner face separated from a side face of the head portion.

In example embodiments of the present invention, the chuck may include an electrostatic chuck, and the chamber comprises a chemical vapor deposition (CVD) chamber.

According to still another aspect of the present invention, there is provided a method of processing a substrate. In the method of processing the substrate, a substrate may be loaded into a chamber. The substrate may be mounted on a chuck using a lift pin moving in a passage formed through the chuck. The passage of the chuck may be closed by a head portion of the lift pin. The substrate may be processed using a reaction gas in the chamber. Reaction by-products generated in processing the substrate may be removed from the chamber.

In processing the substrate according to example embodiments of the present invention, the reaction gas may move into the chamber, and then a plasma may be generated from the reaction gas to form a layer on the substrate.

In example embodiments of the present invention, the substrate may be upwardly moved from the chuck using the lift pin, and then the substrate may be unloaded the substrate from the chamber.

According to example embodiments of the present invention, a lift pin includes a head portion capable of sufficiently closing a passage of a chuck where the lift pin moves upwardly and downwardly, so that the lift pin may effectively prevent reaction by-products and/or a reaction gas from flowing into a passage of a chuck. As a result, failures of a semiconductor device caused by an undesired layer serving as particles may be efficiently prevented because the lift pin may prevent a formation of the undesired layer on the passage while forming a desired layer on an object such as a substrate. Further, it may take longer for cleaning the chuck because the undesired layer may be prevented from being formed, such that a manufacturing cost for the semiconductor device may be reduced and also a life time of the chuck may be improved.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a cross-sectional view illustrating a lift pin in accordance with example embodiments of the present invention;

FIG. 2 is an enlarged cross-sectional view illustrating “II” portion in FIG. 1;

FIG. 3 is a cross-sectional view illustrating a lift pin in accordance with example embodiments of the present invention;

FIG. 4 is a cross-sectional view illustrating a lift pin in accordance with example embodiments of the present invention;

FIG. 5 is a cross-sectional view illustrating a lift pin in accordance with example embodiments of the present invention;

FIG. 6 is a cross-sectional view illustrating a lift pin in accordance with example embodiments of the present invention;

FIG. 7 is a cross-sectional view illustrating a lift pin in accordance with example embodiments of the present invention;

FIG. 8 is a cross-sectional view illustrating an apparatus for processing a substrate in accordance with example embodiments of the present invention; and

FIG. 9 is a flow chart illustrating a method of processing a substrate in accordance with example embodiments of the present invention.

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

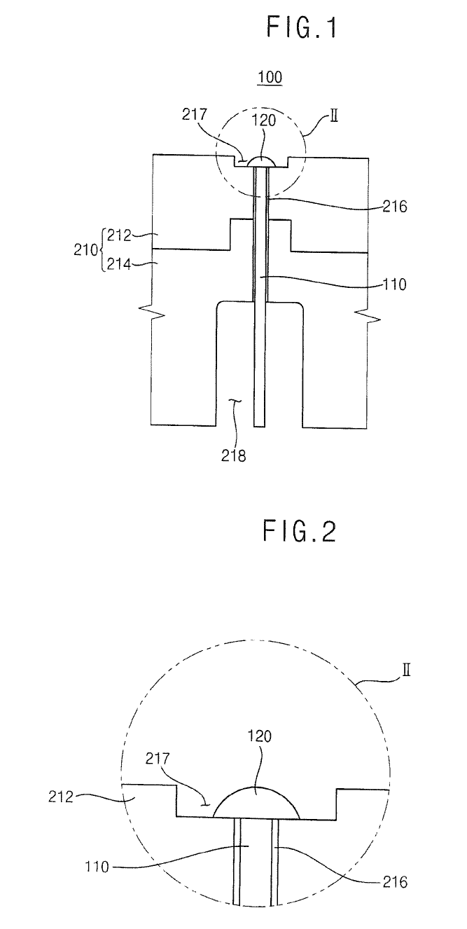

FIG. 1 is a cross-sectional view illustrating a lift pin in accordance with example embodiments of the present invention, and FIG. 2 is an enlarged cross-sectional view illustrating “II” portion in FIG. 1.

Referring to FIGS. 1 and 2, a lift pin 100 includes a rod portion 110 and a head portion 120. In example embodiments, the lift pin 100 may be inserted into a chuck 200 on which an object (not illustrated) such as a substrate is placed.

The rod portion 110 of the lift pin 100 may be inserted into a passage 216 provided through the chuck 210. The passage 216 may be formed along a direction substantially perpendicular to the chuck 210 so that the rod portion 110 may be disposed with respect to the chuck 210. The rod portion 110 may move in the passage 216 along an upward direction and a downward direction. The rod portion 110 may have a width substantially smaller than that of the passage 216. In an example embodiment, the rod portion 110 of the lift pin 100 may have a predetermined width. The rod portion 110 may have a cylindrical structure.

The head portion 120 of the lift pin 100 is provided at one end portion of the rod portion 110. The head portion 120 may be integrally formed with the rod portion 110. The head portion 120 may mount the object such as the substrate on the chuck 210, or the head portion 120 may move the object from the chuck 210 along the upward direction or the downward direction. Since the head portion 120 of the lift pin 100 makes contact with the object, the head portion 120 may have a desired upper portion to reduce a contact area between the lift pin 100 and the object. When the head portion 120 has a reduced upper area, defects of the object, for example, a stain or a spot of the object may be effectively prevented from being generated.

In example embodiments of the present invention, the head portion 120 of the lift pin 100 may have an arch structure or a hemispherical cross-section. Further, the head portion 120 may have a cross-section such as an arc shape or a semicircular shape. When the head portion 120 has the arch structure or the hemispherical structure, the head portion 120 may sufficiently close the passage 216. Thus, the head portion may have a lower width substantially larger than an upper width of the passage 216. In example embodiments, the head portion 120 may seal an upper portion of the passage 216 while forming a desired layer on the object such as the substrate. Therefore, the head portion 120 having the above-described structure may efficiently prevent a reaction gas capable of forming the desired layer from flowing into the passage 216.

In example embodiments of the present invention, a receiving groove 217 is provided at an upper portion of the chuck 210. The head portion 120 of the lift pin 100 may be inserted in the receiving groove 217. The receiving groove 217 may communicate with the passage 216. Since the object is mounted on the chuck 210, the head portion 120 of the lift pin 100 may not protrude from an upper face of the chuck 210. Hence, the receiving groove 217 may have a depth substantially larger than a thickness of the head portion 120. Alternatively, the depth of the receiving groove 217 may be substantially the same as the thickness of the head portion 120. The receiving groove 217 may have a polygonal cross-section, for example, a rectangular cross-section. Here, the head portion 120 may be spaced apart from a side face of the receiving groove 217. That is, the receiving groove 217 may have a width substantially larger than a lower width of the head portion 120.

The chuck 210 provides a space 218 communicating with a lower portion of the passage 216. A holder (not illustrated) is positioned in the space 218 to support a lower portion of the lift pin 100. For example, the holder may support a lower portion of the rod portion 110. In a formation of the layer on the object, an undesired layer may be formed on inner faces of the passage 216 and the space 218 when the reaction gas flows into the space 218 through the passage 216. However, the head portion 110 may close the upper portion of the passage 216 to effectively prevent the reaction gas from flowing into the space 218. Therefore, the undesired layer may not be formed on the inner faces of the passage 216 and the space 218 because of sealing of the passage 216 by the head portion 110.

In example embodiments of the present invention, the head portion 110 of the lift pin 100 may close the passage 216 of the chuck 210 to prevent the reaction gas from flowing into the passage 216 and the space 218. Therefore, the undesired layer may not be formed on the inner faces of the passage 216 and the space 218 by preventing an inflow of the reaction gas into the space 218 through the passage 216.

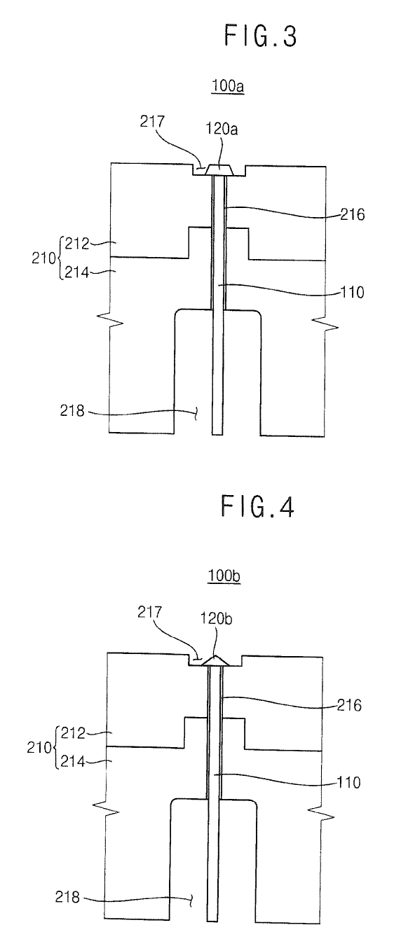

FIG. 3 is a cross-sectional view illustrating a lift pin according to example embodiments of the present invention. In FIG. 3, a lift pin 100a may have a construction substantially similar to or substantially the same as that of the lift pin 100 described with reference to FIGS. 1 and 2 except for a head portion 120a.

Referring to FIG. 3, the head portion 120a of the lift pin 100a may have a trapezoid cross-section. This head portion 120a may have a lower width to sufficiently cover an upper portion of a passage 216 of a chuck 210. Thus, the head portion 120a may have a lower portion substantially wider than an upper portion thereof. In other words, the lower width of the head portion 120a may be substantially larger than an upper width of the head portion 120a.

In example embodiments of the present invention, the head portion 120a is received in a receiving groove 217 of the chuck 210. The head portion 210a may move upwardly from the receiving groove 217 while loading an object on the lift pin 100a. Additionally, the head portion 120a may make contact with a bottom of the receiving groove 217 while mounting the object on the chuck 210. The receiving groove 217 may have a polygonal cross-section such as a rectangular cross-section. A side face of the head portion 120a may be separated from an inner face of the receiving groove 217 by a predetermined distance. Hence, the head portion 120a may have a lower width substantially smaller than a width of the receiving groove 217.

FIG. 4 is a cross-sectional view illustrating a lift pin in accordance with example embodiments of the present invention. In FIG. 4, a lift pin 100b may have a construction substantially similar to or substantially the same as that of the lift pin 100 described with reference to FIGS. 1 and 2 except for a head portion 120b.

Referring to FIG. 4, the lift pin 100b includes the head portion 120b having a polygonal cross-section such as a triangular cross-section. The head portion 120b may have a lower width substantially larger than an upper width of a passage 216 of a chuck 210 to thereby sufficiently close the passage 216 while forming a desired layer on an object such as a substrate.

In example embodiments of the present invention, the head portion 100b is received in a receiving groove 217 of the chuck 210. The head portion 100b may make contact with a bottom of the receiving groove 217 and also may move from the receiving groove 217. The receiving groove 217 may have a rectangular cross-section. An inner face of the receiving groove 217 may be spaced apart from a side face of the head portion 100b because the head portion 100b may have the lower width substantially smaller than a width of the receiving groove 217.

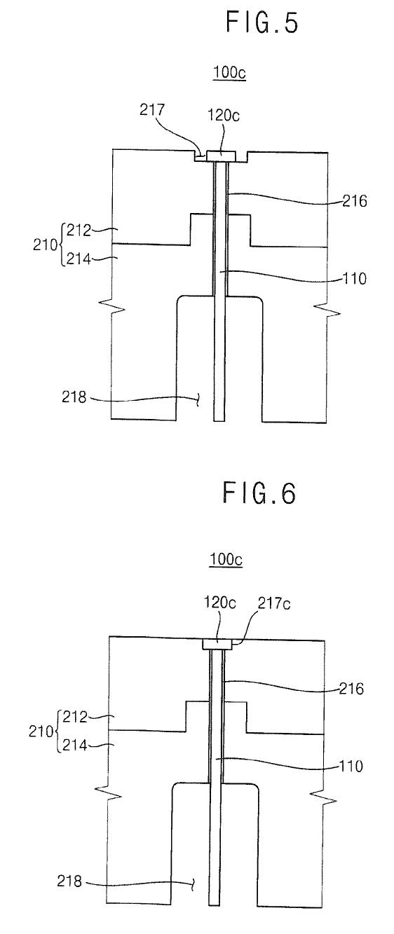

FIGS. 5 and 6 are cross-sectional views illustrating a lift pin in accordance with example embodiments of the present invention. In FIGS. 5 and 6, a lift pin 100c may have a construction substantially similar to or substantially the same as that of the lift pin 100 described with reference to FIGS. 1 and 2 except for a head portion 120c.

Referring to FIG. 5, the head portion 120c of the lift pin 100c may have a polygonal cross-section, for example, a rectangular cross-section. The head portion 120c may have a lower width substantially wider than an upper width of a passage 216 of a chuck 210, so that a reaction gas may not flow into the passage 216 and a space 218 of the chuck 210 while forming a layer on an object. That is, the head portion 120c may sufficiently close the passage 216 to thereby prevent an undesired layer from forming on the passage 216 and the space 218.

In some example embodiments of the present invention, a receiving groove 217 of the chuck 210 is provided to receive the head portion 120c of the lift pin 100c. The receiving groove 217 may have a polygonal cross-section such as a rectangular cross-section. The head portion 120c may have a side face separated from an inner face of the receiving groove 217 because the head portion 120c may have the lower width substantially smaller than a width of the receiving groove 217.

In other example embodiments of the present invention, the head portion 120c may make contact with the receiving groove 217c. That is, a side face of the head portion 120c may come into contact with an inner face of the receiving groove 217c. Here, the receiving groove 217c may have a width slightly larger than a lower width of the head portion 120c, and thus ensure the head portion 120c to move upward. When the head portion 120c makes contact with the receiving groove 217c, an inflow of the reaction gas into the passage 216 may be more effectively prevented.

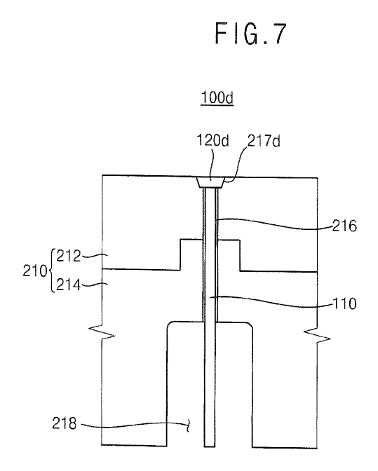

FIG. 7 is a cross-sectional view illustrating a lift pin in accordance with example embodiments of the present invention. In FIG. 7, a lift pin 100d may have a construction substantially similar to or substantially the same as that of the lift pin 100 described with reference to FIGS. 1 and 2 except for a head portion 120d. Additionally, a chuck 210 includes a receiving groove 217d adjusted according to a structure of the head portion 120d.

Referring to FIG. 7, the head portion 120d of the lift pin 100d may have a funnel-shaped cross-section. Namely, the head portion 120a may have an upper width substantially larger than a lower width thereof. However, the lower width of the head portion 120a may be substantially larger than an upper width of a passage 216 of the chuck 210 to sufficiently close the passage 216.

In example embodiments of the present invention, the head portion 120d is received in a receiving groove 217d of the chuck 210. The receiving groove 217d may also have an upper width substantially larger than a lower width thereof. For example, the receiving groove 217d may have a funnel-shaped cross-section. The head portion 120d of the lift pin 100d may make contact with the receiving groove 217d of the chuck 210. That is, a side face of the head portion 120d may contact with an inner face of the receiving groove 217d. The receiving groove 217d may have an upper width slightly larger than the upper width of the head portion 120d, and also a lower width of the receiving 217d may be slightly larger than the lower width of the head portion 120d. Hence, because the receiving groove 217c and the head portion 120c are closely adhered to each other, the reaction gas may be more effectively prevented from flowing into the passage 216 and a space 218 of the chuck 210 while forming a desired layer on an object.

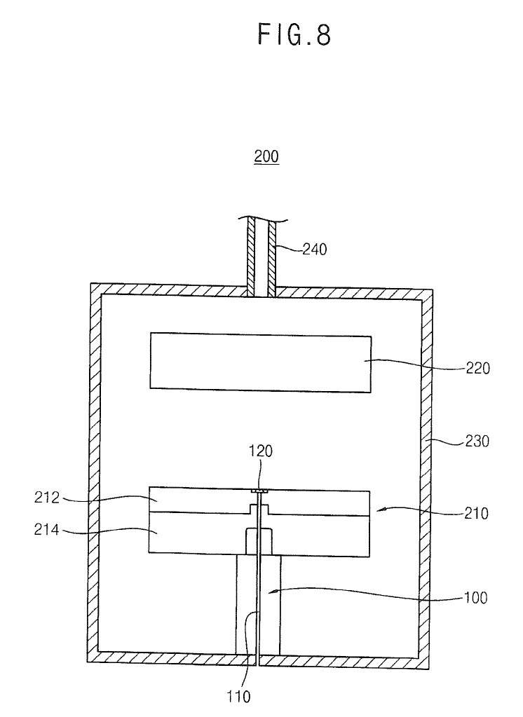

FIG. 8 is a cross-sectional view illustrating an apparatus for processing a substrate in accordance with example embodiments of the present invention. In FIG. 8, although the apparatus such as a chemical vapor deposition (CVD) apparatus is illustrated, the apparatus according to example embodiments of the present invention may correspond to other apparatuses employing the above-described lift pin of the present invention.

Referring to FIG. 8, an apparatus 200 for processing a substrate includes a chamber 230, a chuck 210, a shower head 220 and a lift pin 100.

The chamber 230 may have space where the substrate is placed. The substrate may include a semiconductor substrate such as a silicon substrate, a germanium substrate, a silicon-germanium substrate, etc. An inlet 240 is provided at an upper portion of the chamber 230. A reaction gas for forming a desired layer on the substrate may be introduced into the chamber 230 through the inlet 240. An outlet (not illustrated) is disposed at a lower portion of the chamber 230. After performing a deposition process for forming the layer on the substrate, reaction by-products and remaining reaction gas may be exhausted from the chamber 230 through the outlet.

The chuck 210 is installed in the chamber 230. The chuck 210 may include an electrostatic chuck for supporting the substrate using an electrostatic force. The chuck 210 includes a plate 212 and a heater 214 positioned beneath the plate 212. The substrate may be placed on the plate 212 and may be heated by the heater 214 up to a predetermined temperature. The chuck 210 may further include a power source (not illustrated) electrically connected to the plate 212. While forming the layer on the substrate, the plate 212 may serve as a lower electrode for generating a plasma from the reaction gas in the chamber 230. The chuck 210 may have a construction substantially similar to or substantially the same as that of the chuck described with reference to FIG. 1. Alternatively, the chuck 210 may have a construction substantially similar to or substantially the same as those of the chucks described with reference to FIGS. 3 to 7.

The lift pin 100 may be inserted into the chuck 210 to move in a passage of the chuck 210. For example, the lift pin 100 may move along an upward direction or a downward direction. In some example embodiments, the lift pin 100 may have a construction substantially similar to or substantially the same as that of the lift pin described with reference to FIGS. 1 and 2. In other example embodiments, the lift pin 100 may have a construction substantially similar to or substantially the same as that of the lift pins described with reference to FIGS. 3 to 7.

The shower head 220 is positioned over the chuck 210 in the chamber 230. The shower head 220 may communicate with the inlet 240 to uniformly provide the reaction gas onto the substrate loaded on the chuck 210. The shower head 220 may be electrically connected to a power source (not illustrated) to thereby serve as an upper electrode for generating the plasma from the reaction gas in the chamber 230 while forming the layer on the substrate.

Hereinafter, a method of processing substrate using the above-described apparatus will be described in detail with reference to the accompanying drawings.

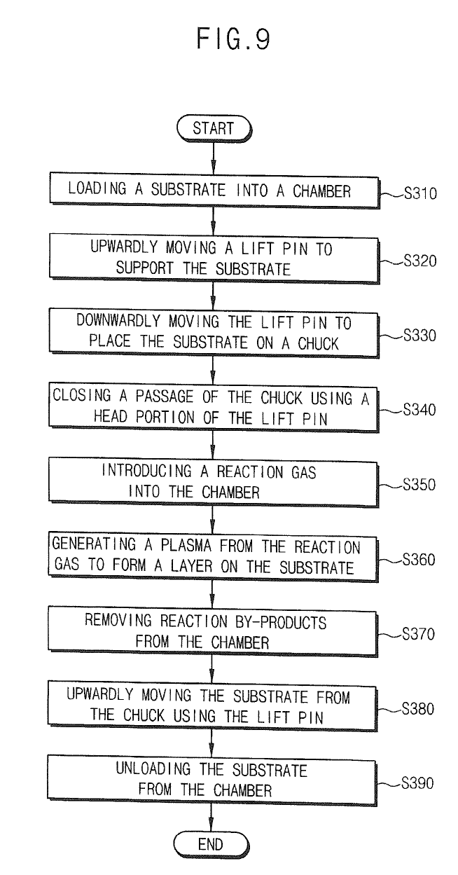

FIG. 9 is a flow chart illustrating a method of processing a substrate in accordance with example embodiments of the present invention. In FIG. 9, the method of processing the substrate may be performed using the apparatus for processing the substrate illustrated in FIG. 8.

Referring to FIGS. 8 and 9, a substrate such as a semiconductor substrate is loaded into the chamber 230 in step S310. The substrate may be inserted into the chamber 230 using a transfer apparatus, for example, a robot arm.

In step S320, the lift pin 100 moves upwardly in the passage of the chuck 210 so that the head portion 120 of the lift pin 100 makes contact with a bottom of the substrate. That is, the substrate is placed on the head portion 120 of the lift pin 100.

In step S330, the lift pin 100 moves downwardly in the passage of the chuck 210 such that the substrate is loaded on the chuck 210.

The head portion 120 of the lift pin 100 is received in the receiving groove of the chuck 210 in step S340. Thus, the passage of the chuck 210 may be closed by the head portion 120 of the lift pin 100.

In step S350, a reaction gas is introduced into the chamber 230 through the inlet 240. The reaction gas may be uniformly distributed in the chamber 230 through the shower head 220.

A voltage is applied to the shower head 220 and the chuck 210 to generate a plasma from the uniformly distributed reaction gas in the chamber 230 in step S360. The plasma may be provided onto the substrate supported by the chuck 210 so that a desired layer may be formed on the substrate. While forming the layer on the substrate, the head portion 120 of the lift pin 100 may close an upper portion of the passage of the chuck 210. Hence, a remaining reaction gas and reaction by-products in the chamber 230 may not flow into the passage of the chuck 210.

In step S370, reaction by-products and a remaining reaction gas are exhausted from the chamber 230 through the outlet after forming the layer on the substrate. The reaction by-products and the remaining reaction gas may be removed from the chamber 230 using a vacuum pump.

In step S380, the substrate moves upwardly from the chuck 210 according as the lift pin 100 moves in the upward direction after removing the reaction by-products and the remaining reaction gas. Since the reaction by-products and the remaining reaction gas are removed from the chamber 230 through the outlet, the reaction by-products and the remaining reaction gas may not flow into the passage of the chuck 210 when the head portion 120 of the lift pin 100 opens the passage of the chuck 210.

The substrate is unloaded from the chamber 230 in step S390. The substrate may be removed from the chamber 230 using the transfer apparatus such as the robot arm.

According to example embodiments of the present invention, although a lift pin is employed together with a chuck in an apparatus for processing a substrate, the lift pin may be advantageously used with other devices for supporting objects such as various substrates for liquid crystal display devices.

According to example embodiments of the present invention, a lift pin includes a head portion capable of sufficiently closing a passage of a chuck where the lift pin moves upwardly and downwardly, so that the lift pin may effectively prevent reaction by-products and/or a reaction gas from flowing into a passage of a chuck. As a result, failures of a semiconductor device caused by an undesired layer serving as particles may be efficiently prevented because the lift pin may prevent a formation of the undesired layer on the passage while forming a desired layer on an object such as a substrate. Further, it may take longer for cleaning the chuck because the undesired layer is prevented from being formed, such that a manufacturing cost for the semiconductor device may be reduced and also a life time of the chuck may be improved.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A lift pin comprising:
a rod portion moving in a passage formed through a chuck having an object processed using a reaction gas; and
a head portion provided on the rod portion to make contact with the object, wherein the head portion closes the passage to prevent the reaction gas from flowing into the passage.

2. The lift pin of claim 1, wherein the head portion has a lower portion making contact with an upper face of the passage of the chuck.

3. The lift pin of claim 1, wherein a receiving groove is provided on the chuck to receive the head portion, and the head portion has a side face separated from an inner face of the receiving groove communicating with the passage.

4. The lift pin of claim 1, wherein a receiving groove is provided on the chuck to receive the head portion, and the head portion has a side face making contact with an inner face of the receiving groove communicating with the passage.

5. The lift pin of claim 1, wherein an upper portion of the head portion is substantially smaller than a lower portion of the head portion.

6. The lift pin of claim 5, wherein the head portion has an arch-shaped cross-section, a semicircular cross-section, a triangular cross-section, a rectangular cross-section, a trapezoid cross-section or a funneled cross-section.

7. An apparatus for processing a substrate, comprising:
a chamber for receiving a substrate;
chuck disposed in the chamber to support the substrate, wherein the chuck has a passage formed along a direction substantially perpendicular to the substrate;
a shower head disposed over the chuck to provide a reaction gas onto the substrate; and
a lift pin disposed in the passage to move the substrate along an upward direction and a downward direction, wherein the lift pin comprises a rod portion moving in the passage and a head portion formed on the rod portion to prevent the reaction gas from flowing into the passage.

8. The apparatus for processing the substrate of claim 7, wherein an upper portion of the head portion of the lift pin is substantially smaller than a lower portion of the head portion.

9. The apparatus for processing the substrate of claim 8, wherein the head portion has an arch-shaped cross-section, a semicircular cross-section, a polygonal cross-section or a funneled cross-section.

10. The apparatus for processing the substrate of claim 7, wherein the chuck has a receiving groove where the head portion is received.

11. The apparatus for processing the substrate of claim 10, wherein the receiving groove has a depth substantially the same as or larger than a thickness of the head portion.

12. The apparatus for processing the substrate of claim 10, wherein the receiving groove has an inner face making contact with a side face of the head portion.

13. The apparatus for processing the substrate of claim 10, wherein the receiving groove has an inner face separated from a side face of the head portion.

14. The apparatus for processing the substrate of claim 7, wherein the chuck comprises an electrostatic chuck.

15. The apparatus for processing the substrate of claim 7, wherein the chamber comprises a chemical vapor deposition (CVD) chamber.

16. A method of processing a substrate, comprising:
loading a substrate into a chamber;
mounting the substrate on a chuck using a lift pin moving in a passage formed through the chuck;
closing the passage by a head portion of the lift pin;
processing the substrate using a reaction gas in the chamber; and
removing reaction by-products generated in processing the substrate from the chamber.

17. The method of processing the substrate of claim 16, wherein processing the substrate comprises:
introducing the reaction gas into the chamber; and
generating a plasma from the reaction gas to form a layer on the substrate.

18. The method of processing the substrate of claim 16, further comprising:
upwardly moving the substrate from the chuck using the lift pin; and
unloading the substrate from the chamber.
